(19) United States
(12) Patent Application Publication
(10) Pub. No.: US 2025/0221117 A1
(43) Pub. Date: Jul. 3, 2025

(54) LED DISPLAY DEVICE

(71) Applicant: AUO Corporation, HSIN-CHU (TW)

(72) Inventors: Sheng-Wen CHENG, HSIN-CHU (TW); Ya-Ting CHEN, HSIN-CHU (TW); Jen-Lang TUNG, HSIN-CHU (TW)

(21) Appl. No.: 18/796,436

(22) Filed: Aug. 7, 2024

(30) Foreign Application Priority Data
Dec. 28, 2023 (TW) 112151441

(51) Int. Cl. H01L 33/60; G02F 1/137; G02F 1/1523; H01L 25/075

(52) U.S. Cl. CPC H10H 20/856; G02F 1/137; G02F 1/1523; H01L 25/0753

(57) ABSTRACT

A light-emitting diode display device includes a translucent display panel, a switchable optical mirror and a switch controller. The translucent display panel has a plurality of light-emitting diodes. The switchable optical mirror is located at a side of the translucent display panel, in which the light-emitting diodes are configured to emit a light beam toward the switchable optical mirror respectively. The switch controller electrically connects the switchable optical mirror and the light-emitting diodes and is configured such that the switchable optical mirror and the light-emitting diodes to switch between a first display state and a second display state synchronously.

### RELATED APPLICATIONS

This application claims priority to Taiwan Application Serial Number 112151441, filed Dec. 28, 2023, which is herein incorporated by reference.

### BACKGROUND

### Field of Invention

The present disclosure relates to a light-emitting diode (LED) display.

### Description of Related Art

In the field of display device, the display devices that can display at both sides are often used as billboard or signboard. In the field of double-side display, the general method is to provide a substrate, and then attach the display device at both sides using the substrate as the center. Although such design can functionally achieve double-side display, but the thickness of two sides of display device is harmful to the thinning of the device, which makes the volume of the display device greater.

### SUMMARY

One aspect of the present disclosure provides a light-emitting diode (LED) display device.

According to one embodiment of the present disclosure, a light-emitting diode display device includes a translucent display panel, a switchable optical mirror and a switch controller. The translucent display panel has a plurality of light-emitting diodes. The switchable optical mirror is located at a side of the translucent display panel, in which the light-emitting diodes are configured to emit a light beam toward the switchable optical mirror respectively. The switch controller electrically connects the switchable optical mirror and the light-emitting diodes and is configured such that the switchable optical mirror and the light-emitting diodes to switch between a first display state and a second display state synchronously.

In some embodiments of the present disclosure, the switchable optical mirror includes a transparent conductive layer, an ion storage layer, an electrolyte layer, a proton injector and a metal hydride mirror layer. The ion storage layer is located on the transparent conductive layer. The electrolyte layer is located on the ion storage layer. The proton injector is located on the ion storage layer. The metal hydride mirror layer is located on the proton injector, in which the metal hydride mirror layer is configured to switch between a transparent state and a reflection state according to a signal of the switch controller.

In some embodiments of the present disclosure, the switchable optical mirror includes a first transparent conductive layer, an electrolyte solution layer, a metal reduction-oxidation (redox) layer and a second transparent conductive layer. The electrolyte solution layer is located on the first transparent conductive layer. The metal reduction-oxidation (redox) layer is located on the electrolyte solution layer, in which the metal redox layer is configured to switch between a transparent state and a reflection state according to a signal of the switch controller. The second transparent conductive layer is located on the metal redox layer.

In some embodiments of the present disclosure, the switchable optical mirror includes a first transparent conductive layer, a second transparent conductive layer and a liquid crystal layer. The liquid crystal layer is located between the first transparent conductive layer and the second transparent conductive layer, in which the liquid crystal layer is configured to switch between a horizontal state and a vertical state according to a signal of the switch controller.

In some embodiments of the present disclosure, the switchable optical mirror includes a transparent conductive layer, a dielectric layer and a flexible mirror layer. The dielectric layer is located on the transparent conductive layer. The flexible mirror layer is located on the dielectric layer, in which the flexible mirror layer is configured to switch between a curled state and a flat state according to a signal of the switch controller.

In some embodiments of the present disclosure, the light-emitting diode (LED) display device further includes a beam pattern modulating layer. The beam pattern modulating layer is located between the light-emitting diodes and the switchable optical mirror.

In some embodiments of the present disclosure, the beam pattern modulating layer is configured to offset a center position of the light beams emitted by the light-emitting diodes.

In some embodiments of the present disclosure, the beam pattern modulating layer is configured to diffuse the light beams emitted by the light-emitting diodes.

In some embodiments of the present disclosure, the light-emitting diode (LED) display device further includes a planarization layer. The planarization layer covers the light-emitting diodes.

In some embodiments of the present disclosure, when the switch controller is configured such that the switchable optical mirror and the light-emitting diodes switch to the first display state synchronously, the light-emitting diodes are switched to display a first display image, and the switchable optical mirror is switched to a global reflection state.

In some embodiments of the present disclosure, when the switch controller is configured such that the switchable optical mirror and the light-emitting diodes switch to the second display state synchronously, the light-emitting diodes are switched to display a second display image, and the switchable optical mirror is switched to a global transparent state.

In some embodiments of the present disclosure, the switch controller is further configured to switch the first display state and the second display state at a time interval.

In some embodiments of the present disclosure, the time interval is smaller than one over sixty seconds.

In some embodiments of the present disclosure, a first portion of the switchable optical mirror corresponds to a first portion of the light-emitting diodes, a second portion of the switchable optical mirror corresponds to a second portion of the light-emitting diodes, the switch controller is configured such that the first portion of the switchable optical mirror and the first portion of the light-emitting diodes switch to the first display state synchronously and such that the second portion of the switchable optical mirror and the second portion of the light-emitting diodes switch to the second display state synchronously, when the switch controller is configured such that the first portion of the switchable optical mirror and the first portion of the light-emitting diodes switch to the first display state synchronously, the first portion of the light-emitting diodes are switched to display a first display image, and the first portion of the switchable optical mirror is switched to a reflection state, when the switch controller is configured such that the second portion of the switchable optical mirror and the second portion of the light-emitting diodes switch to the second display state synchronously, the second portion of the light-emitting diodes are switched to display a second display image, and the second portion of the switchable optical mirror is switched to a transparent state.

In some embodiments of the present disclosure, the switchable optical mirror has a plurality of pixels, a first portion of the pixels corresponds to a first portion of the light-emitting diodes, a second portion of the pixels corresponds to a second portion of the light-emitting diodes, the switch controller is configured such that the first portion of the pixels and the first portion of the light-emitting diodes switch to the first display state synchronously and enable the second portion of the pixels and the second portion of the light-emitting diodes switch to the second display state synchronously, when the switch controller is configured such that the first portion of the pixels and the first portion of the light-emitting diodes switch to the first display state synchronously, the first portion of the light-emitting diodes are switched to display a first display image, and the first portion of the pixels is switched to a reflection state, when the switch controller is configured such that the second portion of the pixels and the second portion of the light-emitting diodes switch to the second display state synchronously, the second portion of the light-emitting diodes is switched to display a second display image, and the second portion of the pixels is switched to a transparent state.

In some embodiments of the present disclosure, the switch controller is further configured such that the first portion of the pixels and the first portion of the light-emitting diodes switch to the second display state synchronously and such that the second portion of the pixels and the second portion of the light-emitting diodes switch to the first display state synchronously at the next frame, when the switch controller is configured such that the first portion of the pixels and the first portion of the light-emitting diodes switch to the second display state synchronously, the first portion of the light-emitting diodes is switched to display the second display image, and the first portion of the pixels is switched to a transparent state, when the switch controller is configured such that the second portion of the pixels and the second portion of the light-emitting diodes switch to the first display state synchronously, the second portion of the light-emitting diodes is switched to display the first display image, and the second portion of the pixels is switched to a reflection state.

In some embodiments of the present disclosure, the switchable optical mirror has a plurality of subpixels, the subpixels and the light-emitting diodes are one-to-one corresponding, and a first portion of the subpixels corresponds to a first portion of the light-emitting diodes, a second portion of the subpixels corresponds to a second portion of the light-emitting diodes, the switch controller is configured such that the first portion of the subpixels and the first portion of the light-emitting diodes switch to the first display state synchronously and such that the second portion of the subpixels and the second portion of the light-emitting diodes switch to the second display state synchronously, when the switch controller is configured such that the first portion of the subpixels and the first portion of the light-emitting diodes switch to the first display state synchronously, the first portion of the light-emitting diodes is switched to display a first display image, and the first portion of the subpixels is switched to a reflection state, when the switch controller is configured such that the second portion of the subpixels and the second portion of the light-emitting diodes switch to the second display state synchronously, the second portion of the light-emitting diodes is switched to display a second display image, and the second portion of the subpixels is switched to a transparent state.

In some embodiments of the present disclosure, the switch controller is further configured such that the first portion of the subpixels and the first portion of the light-emitting diodes switch to the second display state synchronously and such that the second portion of the subpixels and the second portion of the light-emitting diodes switch to the first display state synchronously at the next frame, when the switch controller is configured such that the first portion of the subpixels and the first portion of the light-emitting diodes switch to the second display state synchronously, the first portion of the light-emitting diodes is switched to display the second display image, and the first portion of the subpixels is switched to a transparent state, when the switch controller is configured such that the second portion of the subpixels and the second portion of the light-emitting diodes switch to the first display state synchronously, the second portion of the light-emitting diodes is switched to display the first display image, and the second portion of the subpixels is switched to a reflection state.

Another aspect of the present disclosure provides a light-emitting diode (LED) display device.

According to one embodiment of the present disclosure, a light-emitting diode display device includes a translucent display panel, a switchable optical mirror and a switch controller. The translucent display panel has a plurality of light-emitting diodes. The switchable optical mirror is located at a side of the translucent display panel. The switch controller electrically connects the switchable optical mirror and the light-emitting diodes and is configured such that the switchable optical mirror and the light-emitting diodes to switch between a first display state and a second display state synchronously.

Another aspect of the present disclosure provides a light-emitting diode (LED) display device.

According to one embodiment of the present disclosure, a light-emitting diode display device includes a translucent display panel, a switchable optical mirror and a switch controller. The translucent display panel has a plurality of light-emitting diodes. The switchable optical mirror is located at a side of the translucent display panel. The switch controller electrically connects the switchable optical mirror and the light-emitting diodes and is configured such that the switchable optical mirror and the light-emitting diodes to switch between a first display state and a second display state synchronously, in which when in global switch mode, the switch controller is configured such that the switchable optical mirror and the light-emitting diodes switch to the second display state synchronously, the light-emitting diodes are switched to display a second display image, and the switchable optical mirror is switched to a global transparent state.

In some embodiments of the present disclosure, when the switch controller is configured such that the switchable optical mirror and the light-emitting diodes switch to the first display state synchronously, the light-emitting diodes are switched to display a first display image, and the switchable optical mirror is switched to a global reflection state.

In the aforementioned embodiments of the present disclosure, since the switchable optical mirror is used in the LED display device, and the switch controller is used such that the LEDs and the switchable optical mirror switch between the first display state and the second display state synchronously, the effect of double-side display can be achieved and simultaneously shrinking the thickness of the device such that the double-side-displayed LED display device is more thin and short, which is beneficial to improve the competitiveness of the product.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a LED display device according to one embodiment of the present disclosure.

FIG. 2 to FIG. 9 are cross-sectional views of switchable optical mirrors according to different embodiments of the present disclosure.

FIG. 10 is a top view of a beam pattern modulating layer according to one embodiment of the present disclosure.

FIG. 11 is a cross-sectional view of the beam pattern modulating layer of FIG. 10 offsetting light beams.

FIG. 12 is a top view of a beam pattern modulating layer according to another embodiment of the present disclosure.

FIG. 13 is a cross-sectional view of the beam pattern modulating layer of FIG. 12 diffusing light beams.

FIG. 14 to FIG. 17 are cross-sectional views of synchronously switching of switchable optical mirror and light-emitting diodes according to different embodiments of the present disclosure.

FIG. 18 is a top view of the LED display device of FIG. 17.

FIG. 19 is a cross-sectional view of synchronously switching of switchable optical mirror and light-emitting diodes according to another embodiment of the present disclosure.

FIG. 20 is a top view of the LED display device of FIG. 19.

FIG. 21 and FIG. 22 are local schematic views of the switchable optical mirror and the light-emitting diode according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

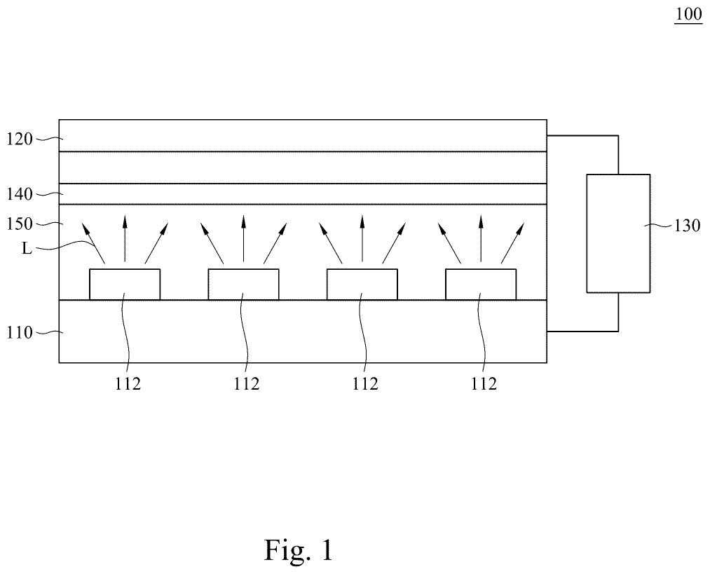

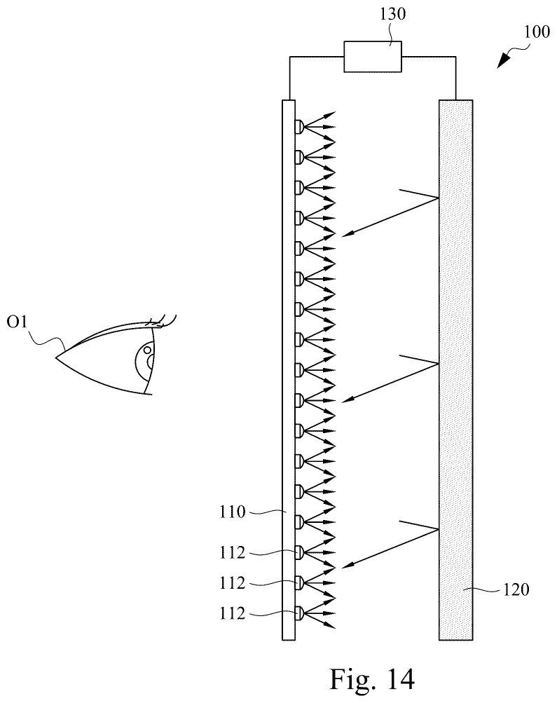

FIG. 1 is a cross-sectional view of a LED display device 100 according to one embodiment of the present disclosure. Refer to FIG. 1, a light-emitting diode (LED) display device 100 includes a translucent display panel 110, a switchable optical mirror 120 and a switch controller 130. The translucent display panel 110 has a plurality of light-emitting diodes 112. In FIG. 1, the translucent display panel 110 is shown to have four LEDs 112, but the disclosure is not limited to this. The switchable optical mirror 120 is located at a side of the translucent display panel 110, in which the LEDs 112 are configured to emit a light beam L toward the switchable optical mirror 120 respectively. The switch controller 130 electrically connects the switchable optical mirror 120 and the LEDs 112 and is configured such that the switchable optical mirror 120 and the LEDs 112 to switch between a first display state and a second display state synchronously. In some embodiments, the switchable optical mirror will be different between the first display state and the second display state. For example, the first display state is a reflection state, the second display state is a transparent state to be beneficial to double-side display, which will be discuss in FIG. 14.

Since the switchable optical mirror 120 is used in the LED display device 100, and the switch controller 130 is used such that the LEDs 112 and the switchable optical mirror 120 switch between the first display state and the second display state synchronously, the effect of double-side display can be achieved and simultaneously shrinking the thickness of the device such that the double-side-displayed LED display device 100 is more thin and short, which is beneficial to improve the competitiveness of the product.

In some embodiments, the LED display device 100 further includes a beam pattern modulating layer 140. The beam pattern modulating layer 140 is located between the LEDs 112 and the switchable optical mirror 120. In some embodiments, the LED display device 100 further includes a planarization layer 150. The planarization layer 150 covers the LEDs 112. In some embodiments, the LED display device further includes retaining walls (not shown in the figure). The retaining walls are located between two LEDs 112 to stop the optical interference between the LEDs 112.

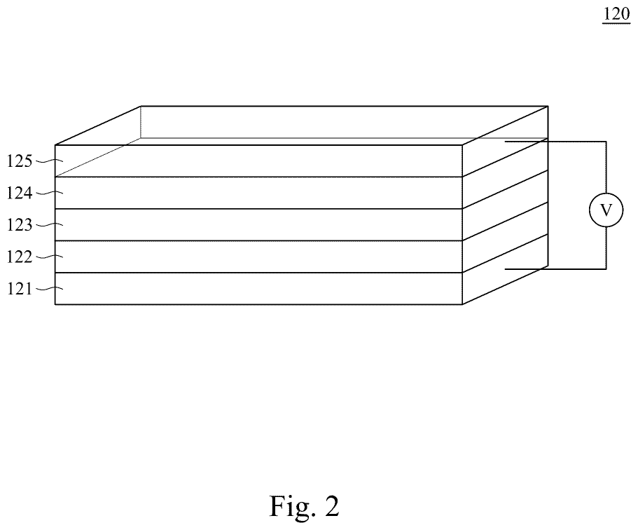

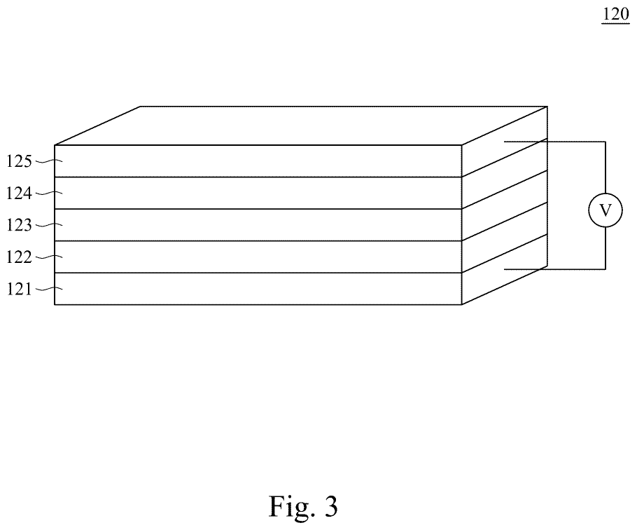

FIG. 2 to FIG. 9 are cross-sectional views of switchable optical mirrors 120, 120a, 120b, 120c according to different embodiments of the present disclosure. Refer to FIG. 2 and FIG. 3, in some embodiments, the switchable optical mirror 120 includes a transparent conductive layer 121, an ion storage layer 122, an electrolyte layer 123, a proton injector 124 and a metal hydride mirror layer 125. The ion storage layer 122 is located on the transparent conductive layer 121. The electrolyte layer 123 is located on the ion storage layer 122. The proton injector 124 is located on the electrolyte layer 123. The metal hydride mirror layer 125 is located on the proton injector 124, in which the metal hydride mirror layer 125 is configured to switch between a transparent state and a reflection state according to a signal of the switch controller 130 (see FIG. 1). In the present embodiment, the material of the transparent conductive layer 121 is indium tin oxide (ITO). The material of the ion storage layer 122 is tungsten oxide (WO₃). The material of the electrolyte layer 123 is tantalum oxide (Ta₂O₅). The material of the proton injector 124 is palladium (Pd). The material of the metal hydride mirror layer 125 is magnesium-nickel alloy. The metal hydride mirror layer 125 will extract proton (i.e. hydrogen ion) and form metal hydride. Metal hydride is a transparent state (such as FIG. 2), while metal state is a reflection state (such as FIG. 3). When switching into the reflection state, the material of the ion storage layer 122 will change into tungsten oxide hydride (H₃WO₃), the material of the metal hydride mirror layer 125 will change into the hydride of magnesium-nickel alloy.

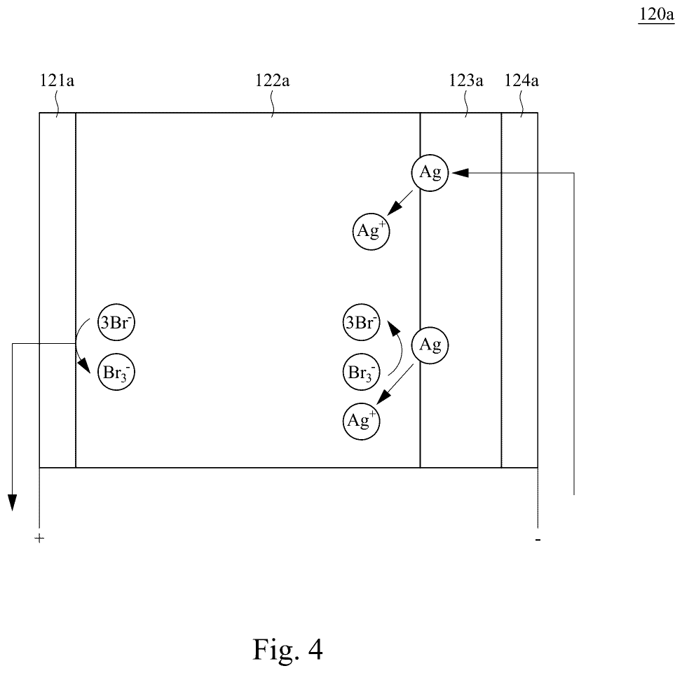

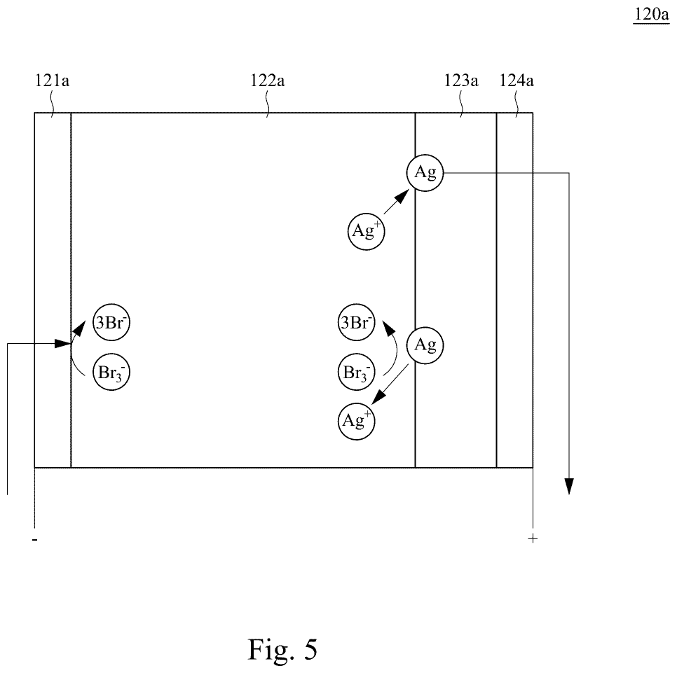

Refer to FIG. 4 and FIG. 5, the switchable optical mirror 120a includes a first transparent conductive layer 121a, an electrolyte solution layer 122a, a metal reduction-oxidation (redox) layer 123a and a second transparent conductive layer 124a. The electrolyte solution layer 122a is located on the first transparent conductive layer 121a. The metal redox layer 123a is located on the electrolyte solution layer 122a, in which the metal redox layer 123a is configured to switch between a transparent state and a reflection state according to a signal of the switch controller 130 (see FIG. 1). The second transparent conductive layer 124a is located on the metal redox layer 123a. In the present embodiment, the material of the first transparent conductive layer 121a and the second transparent conductive layer 124a are indium tin oxide. The material of the metal redox layer 123a is silver. The metal redox layer 123a can decide whether the silver will oxidize into silver ion (which is a transparent state, see FIG. 5) or reduce to silver atom and go back to the metal redox layer 123a (which is a reflection state, see FIG. 4) according to positive or negative bias.

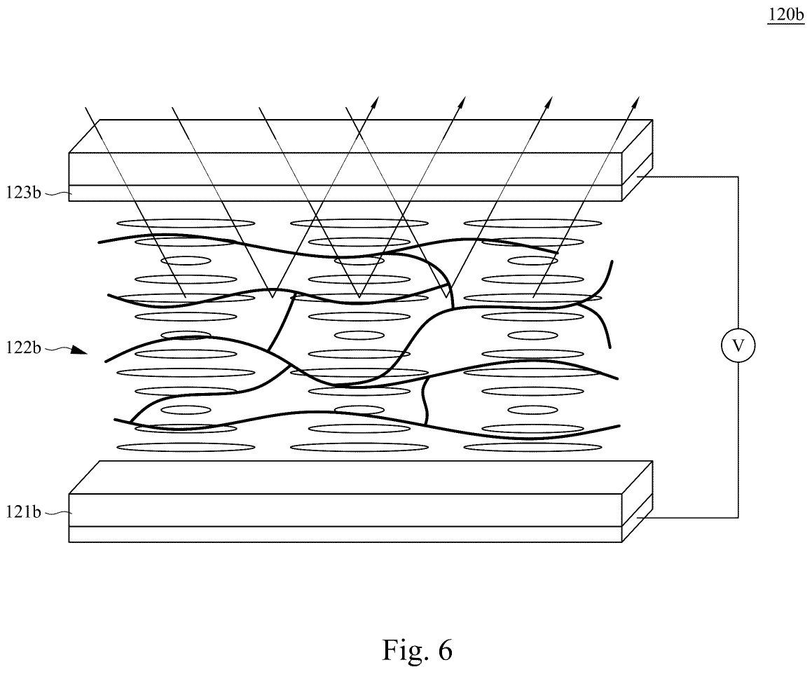

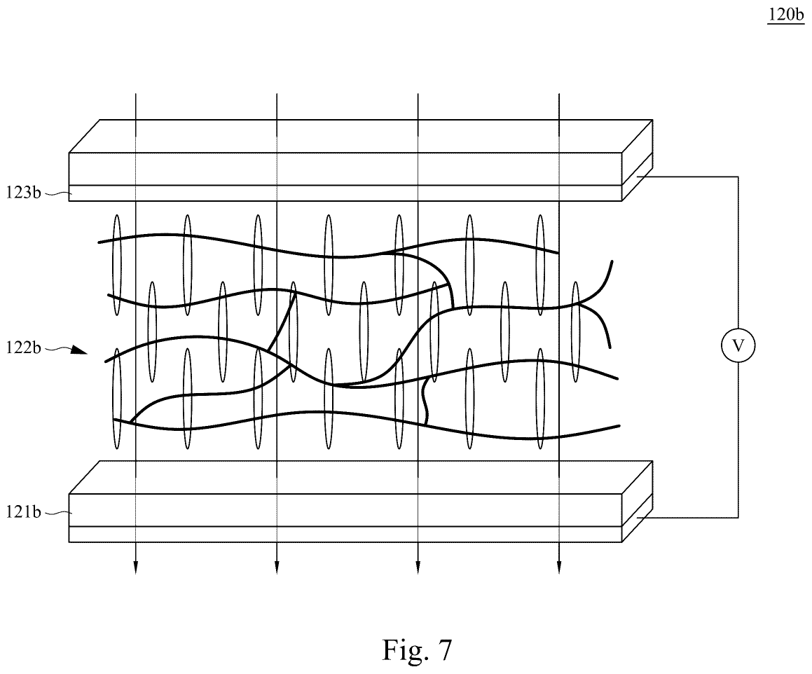

Refer to FIG. 6 and FIG. 7, the switchable optical mirror 120b includes a first transparent conductive layer 121b, a liquid crystal layer 122b and a second transparent conductive layer 123b. The liquid crystal layer 122b is located between the first transparent conductive layer 121b and the second transparent conductive layer 123b, in which the liquid crystal layer is configured to switch between a horizontal state and a vertical state according to a signal of the switch controller 130 (see FIG. 1). The liquid crystal molecules in the liquid crystal layer 122b can rotate between the horizontal state and the vertical state according to electrical signal. The horizontal state is the reflection state of the switchable optical mirror 120b, while the vertical state is the transparent state of the switchable optical mirror 120b.

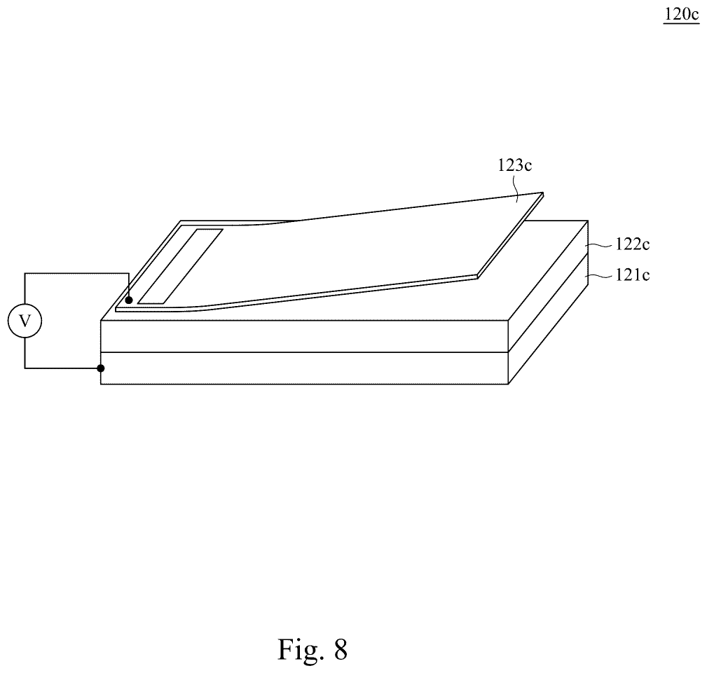

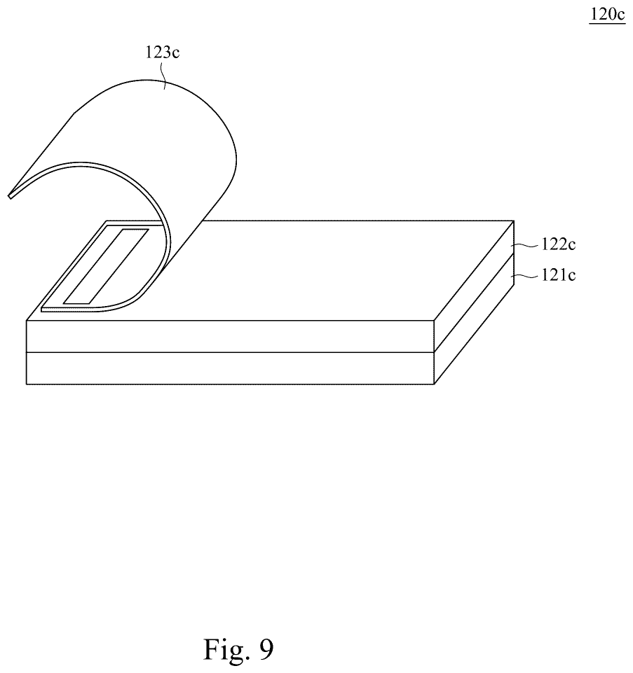

Refer to FIG. 8 and FIG. 9, the switchable optical mirror 120c includes a transparent conductive layer 121c, a dielectric layer 122c and a flexible mirror layer 123c. The dielectric layer 122c is located on the transparent conductive layer 121c. The flexible mirror layer 123c is located on the dielectric layer 122c, in which the flexible mirror layer 123c is configured to switch between a curled state and a flat state according to a signal of the switch controller 130 (see FIG. 1). The flexible mirror layer 123c is a thin layer of metal, which curls when it's electrified. Since most of the flexible mirror layer 123c (only the contact portion on the left) has left the surface of the switchable optical mirror 120c, most of the light can transmit (see FIG. 9). When the flexible mirror layer 123c is not electrified, the flexible mirror layer 123c will fit on the surface of the switchable optical mirror 120c, which is the reflection state of the switchable optical mirror 120c (see FIG. 8).

The switchable optical mirrors 120, 120a, 120b, 120c described above can be freely implemented in the switchable optical mirror 120 of the LED display device 100.

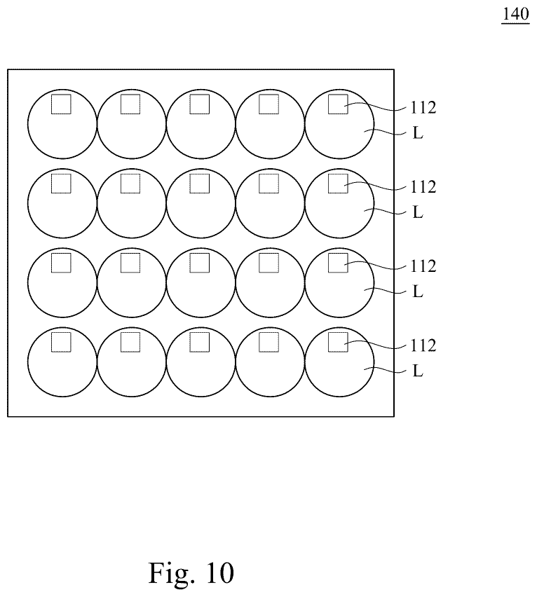

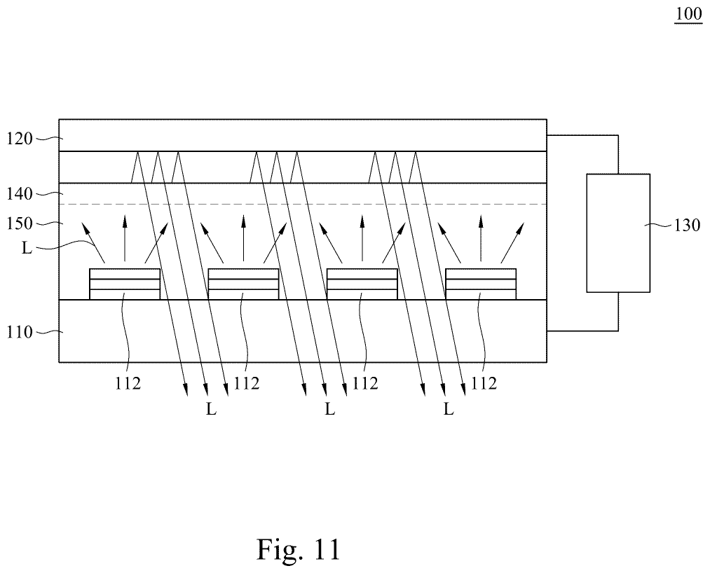

FIG. 10 is a top view of a beam pattern modulating layer 140 according to one embodiment of the present disclosure. FIG. 11 is a cross-sectional view of the beam pattern modulating layer 140 of FIG. 10 offsetting light beams L. Refer to FIG. 10 and FIG. 11, in some embodiments, the beam pattern modulating layer is configured to offset a center position of the light beams L emitted by the LEDs 112. Such design can offset the position of the center of bright spot, which improves the brightness of the light beam L of the LEDs 112 when reflected by the switchable optical mirror 120.

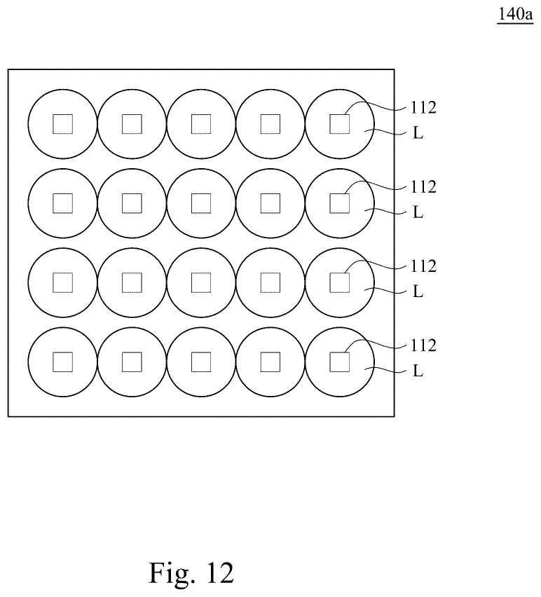

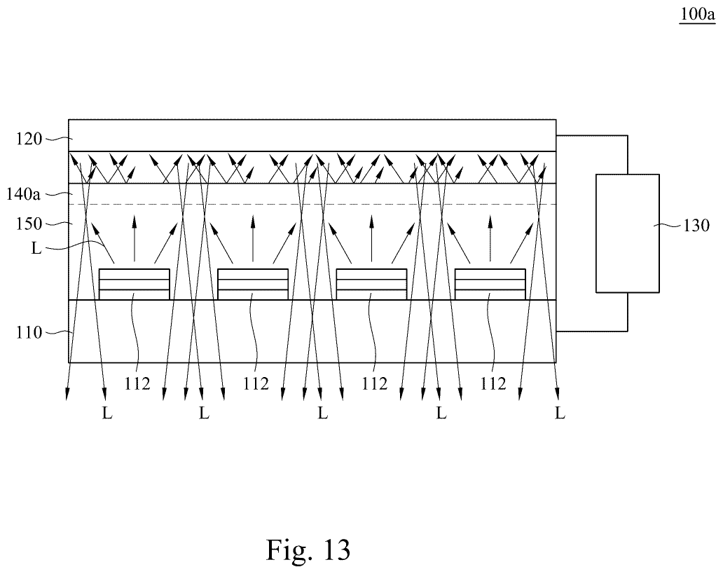

FIG. 12 is a top view of a beam pattern modulating layer 140a according to another embodiment of the present disclosure. FIG. 13 is a cross-sectional view of the beam pattern modulating layer 140a of FIG. 12 diffusing light beams L. Refer to FIG. 12 and FIG. 13, The LED display device 100a includes a beam pattern modulating layer 140a. The beam pattern modulating layer 140a is configured to diffuse the light beams L emitted by the LEDs 112. Such design can diffuse the bright spot, such that when the light beams L of the LEDs 112 are reflected by the switchable optical mirror 120, the portion of the light beams L that is covered by the LEDs 112 that isn't translucent can be decrease.

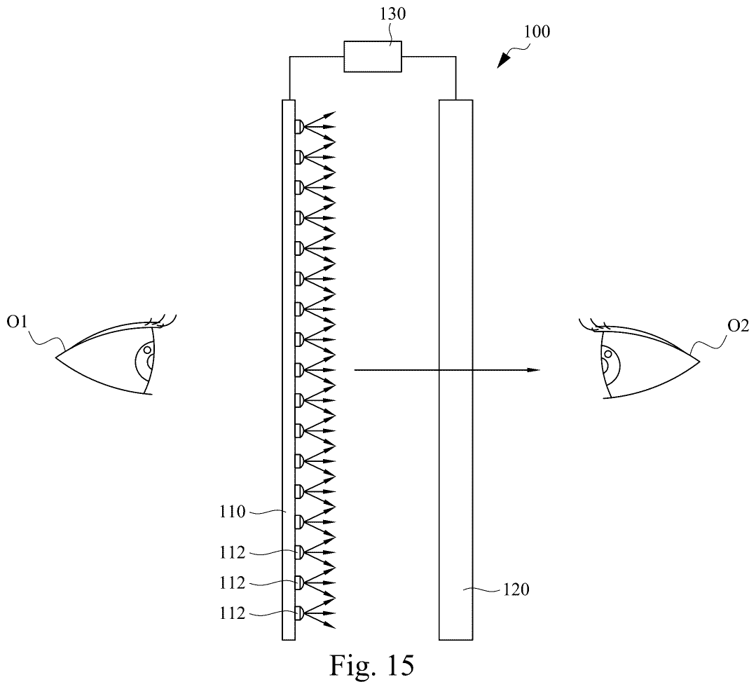

FIG. 14 to FIG. 17 are cross-sectional views of synchronously switching of switchable optical mirror 120 and light-emitting diodes 112 according to different embodiments of the present disclosure. Refer to FIG. 14 and FIG. 15, the switch controller is configured such that the switchable optical mirror 120 and the LEDs 112 to switch synchronously. When the switch controller 130 let the switchable optical mirror 120 and the LEDs 112 switch to the first display state synchronously, the LEDs 112 are switched to display a first display image, and the switchable optical mirror 120 is switched to a global reflection state (such as FIG. 14). At this time, the observer O1 on the left side of the LED display device 100 can see the first display image. When the switch controller 130 let the switchable optical mirror 120 and the LEDs 112 switch to the second display state synchronously, the LEDs 112 are switched to display a second display image, and the switchable optical mirror 120 is switched to a global transparent state (such as FIG. 15). At this time, the observer O2 on the right side of the LED display device 100 can see the second display image, while the observer O1 on the left side of the LED display device 100 will see a totally transparent state. Such mode is called “global switch”, which means the whole switchable optical mirror 120 switch simultaneously between the first display state and the second display state. In some embodiments, the first display image can be different than the second display image. In some embodiments, the switch controller 130 is further configured to switch the first display state and the second display state at a time interval. The time interval is smaller than one over sixty seconds.

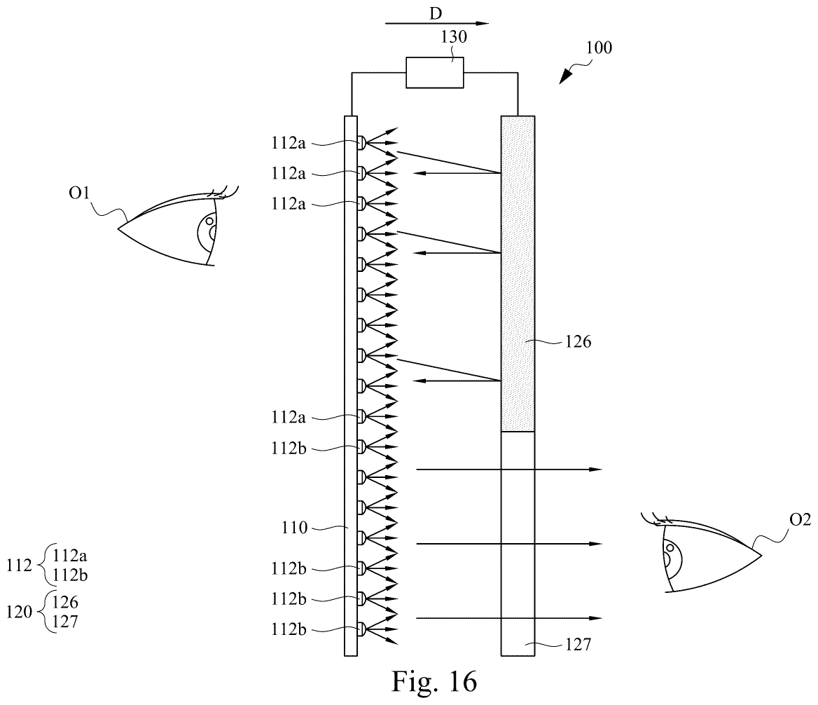

Refer to FIG. 16, in the embodiment of FIG. 16, the switchable optical mirror 120 does not use global switch, but “local switch.” In the present embodiment, the switchable optical mirror 120 is consist of a first portion 126 and a second portion 127, and the LEDs 112 are also divided into a first portion 112a and a second portion 112b. Also, the first portion 126 of the switchable optical mirror 120 corresponds to the first portion 112a of the LEDs 112, the second portion 127 of the switchable optical mirror 120 corresponds to the second portion 112b of the LEDs 112. In the present disclosure, “correspond to” means to face each other along the horizontal direction. Meanwhile, the switch controller 130 will let the first portion 126 of the switchable optical mirror 120 and the first portion 112a of the LEDs 112 switch to the first display state synchronously and let the second portion 127 of the switchable optical mirror 120 and the second portion 112b of the LEDs 112 switch to the second display state synchronously. When the switch controller 130 is configured such that the first portion 126 of the switchable optical mirror 120 and the first portion 112a of the LEDs 112 switch to the first display state synchronously, the first portion 112a of the LEDs 112 are switched to display a first display image, and the first portion 126 of the switchable optical mirror 120 is switched to a reflection state. When the second portion 127 of the switchable optical mirror 120 and the second portion 112b of the LEDs 112 switch to the second display state synchronously, the second portion 112b of the LEDs 112 are switched to display a second display image, and the second portion 127 of the switchable optical mirror 120 is switched to a transparent state. At this state, the observers O1, O2 at two sides of the LED display device 100 can see two part of the image of the LED display device 100 respectively, and the position of the display image that the observer O1 sees does not overlap with the position of the display image that the observer O2 sees.

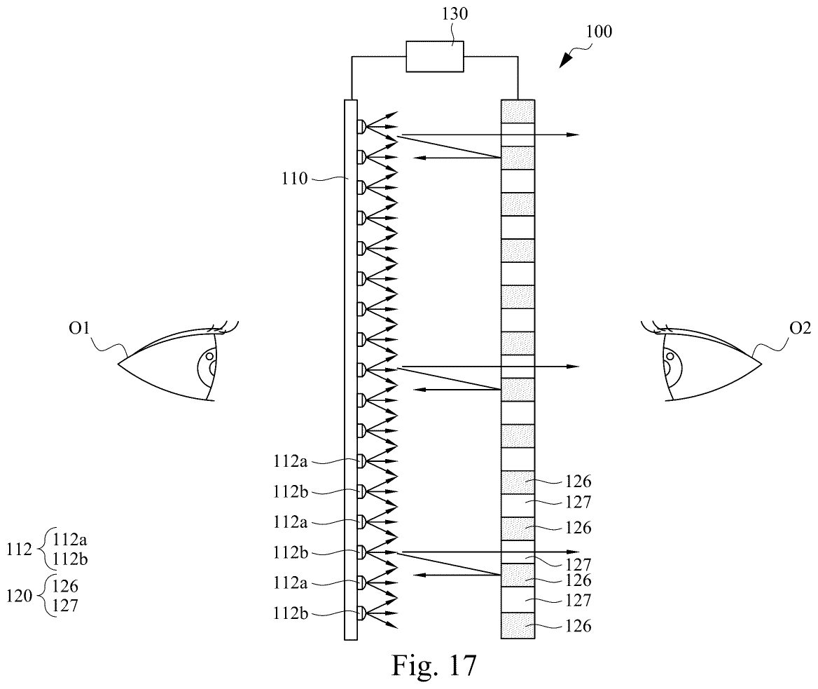

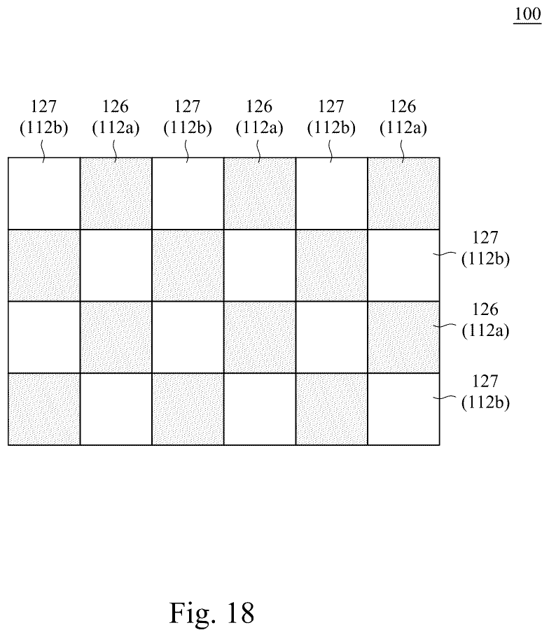

FIG. 18 is a top view of the LED display device 100 of FIG. 17. Refer to FIG. 17 and FIG. 18, the difference between the embodiment of FIG. 17 and FIG. 18 and the embodiment of FIG. 16 is that, in the present embodiment, the switchable optical mirror 120 has a plurality of pixels, a first portion 126 of the pixels corresponds to a first portion 112a of the LEDs 112, a second portion 127 of the pixels corresponds to a second portion 112b of the LEDs 112. In other words, in the present embodiment, the first portion 126 and the second portion 127 of the switchable optical mirror 120 is divided into pixel level. Also, the first portion 112a and the second portion 112b of the LEDs 112 are divided into pixel level. Such design can let the observers O1, O2 at both sides of the LED display device 100 can see a complete image (only a decrease in resolution), and the image display on the two sides can be different.

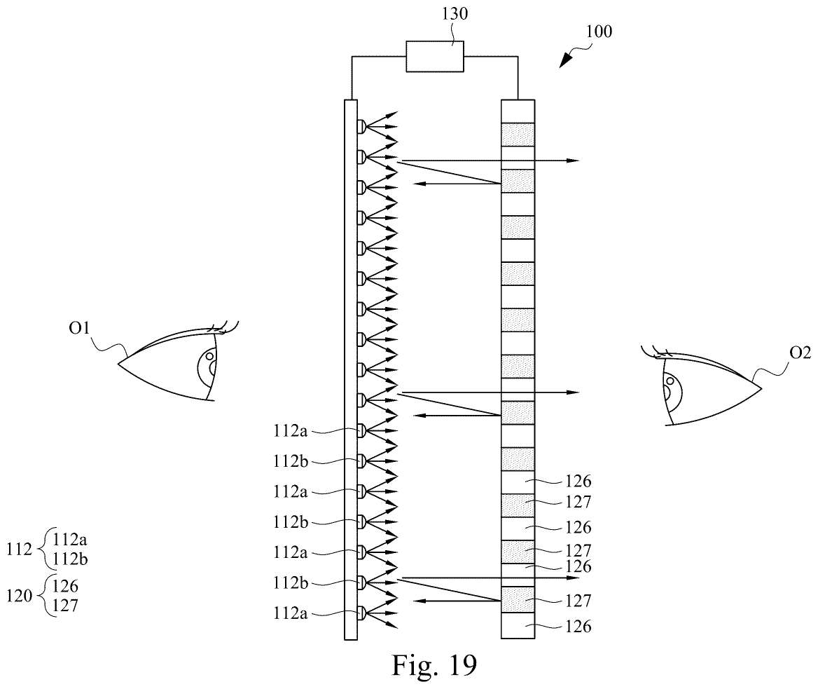

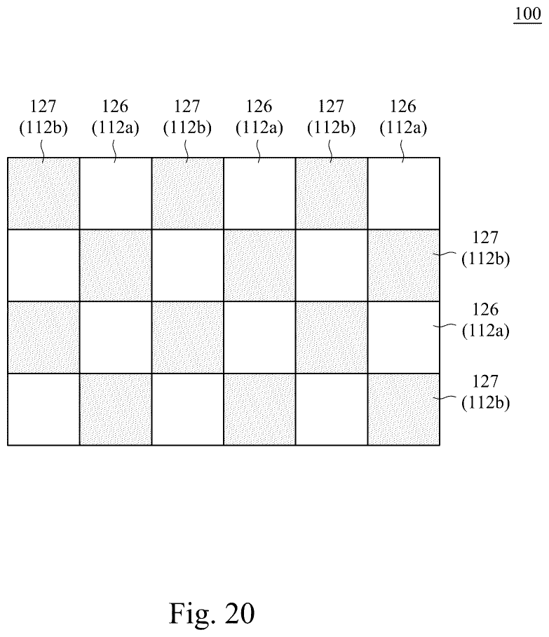

FIG. 19 is a cross-sectional view of synchronously switching of switchable optical mirror 120 and LEDs 112 according to another embodiment of the present disclosure. FIG. 20 is a top view of the LED display device 100 of FIG. 19. Refer to FIG. 19 and FIG. 20, the switch controller 130 is further configured such that the first portion 126 of the pixels and the first portion 112a of the LEDs 112 switch to the second display state synchronously and such that the second portion 127 of the pixels and the second portion 112b of the LEDs 112 switch to the first display state synchronously at the next frame. When the switch controller let the first portion 126 of the pixels and the first portion 112a of the LEDs 112 switch to the second display state synchronously, the first portion 112a of the LEDs 112 is switched to display the second display image, and the first portion 126 of the pixels is switched to a transparent state, when the switch controller is configured such that the second portion 127 of the pixels and the second portion 112b of the LEDs 112 switch to the first display state synchronously, the second portion 112b of the LEDs 112 is switched to display the first display image, and the second portion of the pixels is switched to a reflection state. In other words, the first portion 126 of the pixels will switch between reflection state and transparent state every frame, and the first portion 112a of the LEDs 112 will switch between the first display image and the second display image every frame. Such design can let LED display device 100 produce a fast-switching complementary images, while maintaining observer O1 seeing the first display image and observer O2 seeing the second display image. In some embodiments, the switching speed of the images can be increased by increasing the numbers of the switching of the frame (which equals to increasing frame rate.)

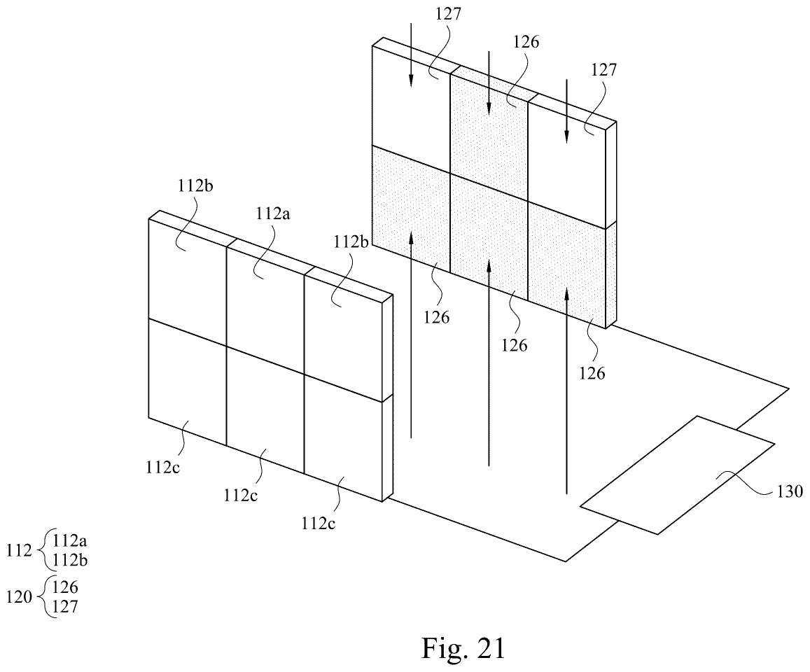

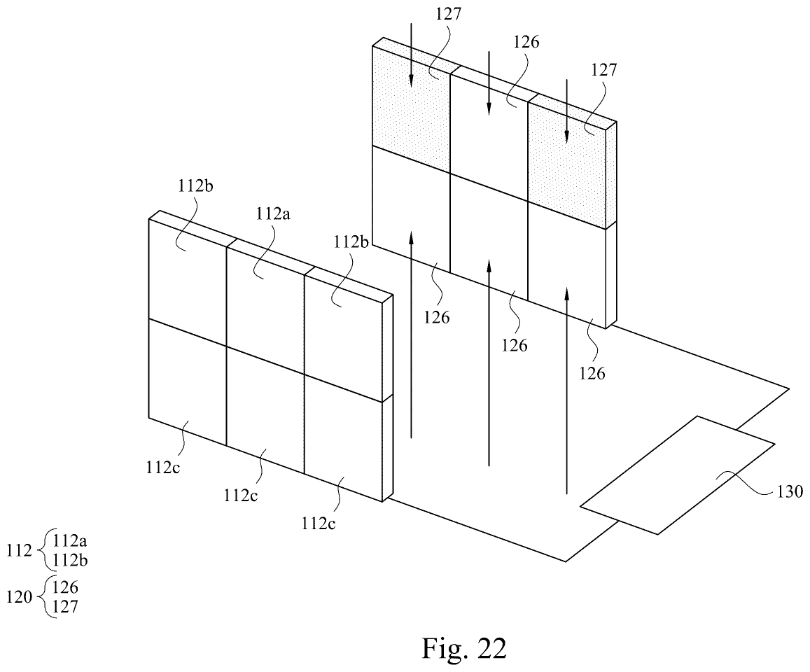

FIG. 21 and FIG. 22 are local schematic views of the switchable optical mirror 120 and the LEDs 112 according to one embodiment of the present disclosure. Refer to FIG. 21 and FIG. 22, the difference between the embodiment of FIG. 21 and FIG. 22 and the embodiment of FIG. 17 to FIG. 20 is that, in the present embodiment, the switchable optical mirror 120 has a plurality of subpixels, the subpixels and the LEDs 112 are one-to-one corresponding, and a first portion 126 of the subpixels corresponds to a first portion 112a of the LEDs 112, a second portion 127 of the subpixels corresponds to a second portion 112b of the LEDs 112. In other words, in the present embodiment, the controlling of the switchable optical mirror 120 is divided into subpixel level. Furthermore, the switch controller 130 is further configured such that the first portion 126 of the subpixels and the first portion 112a of the LEDs 112 switch to the second display state synchronously and such that the second portion 127 of the subpixels and the second portion 112b of the LEDs 112 switch to the first display state synchronously at the next frame. In other words, the switch controller 130 is configured to let the switchable optical mirror 120 and the LEDs 112 can switch like the embodiment in FIG. 17 to FIG. 20, such that the observers at both sides always sees their own image. Also, apart from the area that the LEDs 112 are disposed, there are also subpixel transparent area 112c. The arrangement of the subpixel of the LEDs 112 and the subpixel transparent area 112c are not limited to this.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting diode display device, comprising:
a translucent display panel having a plurality of light-emitting diodes;
a switchable optical mirror located at a side of the translucent display panel, wherein the light-emitting diodes are configured to emit a light beam toward the switchable optical mirror respectively; and
a switch controller electrically connected the switchable optical mirror and the light-emitting diodes and configured to enable the switchable optical mirror and the light-emitting diodes to switch between a first display state and a second display state synchronously.

2. The light-emitting diode display device of claim 1, wherein the switchable optical mirror comprises:
a transparent conductive layer;
an ion storage layer located on the transparent conductive layer;
an electrolyte layer located on the ion storage layer;
a proton injector located on the ion storage layer; and
a metal hydride mirror layer located on the proton injector, wherein the metal hydride mirror layer is configured to switch between a transparent state and a reflection state according to a signal of the switch controller.

3. The light-emitting diode display device of claim 1, wherein the switchable optical mirror comprises:
a first transparent conductive layer;
an electrolyte solution layer located on the first transparent conductive layer;
a metal reduction-oxidation (redox) layer located on the electrolyte solution layer, wherein the metal redox layer is configured to switch between a transparent state and a reflection state according to a signal of the switch controller; and
a second transparent conductive layer located on the metal redox layer.

4. The light-emitting diode display device of claim 1, wherein the switchable optical mirror comprises:
a first transparent conductive layer;
a second transparent conductive layer; and
a liquid crystal layer located between the first transparent conductive layer and the second transparent conductive layer, wherein the liquid crystal layer is configured to switch between a horizontal state and a vertical state according to a signal of the switch controller.

5. The light-emitting diode display device of claim 1, wherein the switchable optical mirror comprises:
a transparent conductive layer;
a dielectric layer located on the transparent conductive layer;
a flexible mirror layer located on the dielectric layer, wherein the flexible mirror layer is configured to switch between a curled state and a flat state according to a signal of the switch controller.

6. The light-emitting diode display device of claim 1, further comprising:
a beam pattern modulating layer located between the light-emitting diodes and the switchable optical mirror.

7. The light-emitting diode display device of claim 6, wherein the beam pattern modulating layer is configured to offset a center position of the light beams emitted by the light-emitting diodes.

8. The light-emitting diode display device of claim 6, wherein the beam pattern modulating layer is configured to diffuse the light beams emitted by the light-emitting diodes.

9. The light-emitting diode display device of claim 1, further comprising:
a planarization layer covering the light-emitting diodes.

10. The light-emitting diode display device of claim 1, wherein when the switch controller is configured such that the switchable optical mirror and the light-emitting diodes switch to the first display state synchronously, the light-emitting diodes are switched to display a first display image, and the switchable optical mirror is switched to a global reflection state.

11. The light-emitting diode display device of claim 1, wherein when the switch controller is configured such that the switchable optical mirror and the light-emitting diodes switch to the second display state synchronously, the light-emitting diodes are switched to display a second display image, and the switchable optical mirror is switched to a global transparent state.

12. The light-emitting diode display device of claim 1, wherein the switch controller is further configured to switch the first display state and the second display state at a time interval.

13. The light-emitting diode display device of claim 12, wherein the time interval is smaller than one over sixty seconds.

14. The light-emitting diode display device of claim 1, wherein a first portion of the switchable optical mirror corresponds to a first portion of the light-emitting diodes, a second portion of the switchable optical mirror corresponds to a second portion of the light-emitting diodes, the switch controller is configured such that the first portion of the switchable optical mirror and the first portion of the light-emitting diodes switch to the first display state synchronously and such that the second portion of the switchable optical mirror and the second portion of the light-emitting diodes switch to the second display state synchronously, when the switch controller is configured such that the first portion of the switchable optical mirror and the first portion of the light-emitting diodes switch to the first display state synchronously, the first portion of the light-emitting diodes are switched to display a first display image, and the first portion of the switchable optical mirror is switched to a reflection state, when the switch controller is configured such that the second portion of the switchable optical mirror and the second portion of the light-emitting diodes switch to the second display state synchronously, the second portion of the light-emitting diodes are switched to display a second display image, and the second portion of the switchable optical mirror is switched to a transparent state.

15. The light-emitting diode display device of claim 1, wherein the switchable optical mirror has a plurality of pixels, a first portion of the pixels corresponds to a first portion of the light-emitting diodes, a second portion of the pixels corresponds to a second portion of the light-emitting diodes, the switch controller is configured such that the first portion of the pixels and the first portion of the light-emitting diodes switch to the first display state synchronously and such that the second portion of the pixels and the second portion of the light-emitting diodes switch to the second display state synchronously, when the switch controller is configured such that the first portion of the pixels and the first portion of the light-emitting diodes switch to the first display state synchronously, the first portion of the light-emitting diodes are switched to display a first display image, and the first portion of the pixels is switched to a reflection state, when the switch controller is configured such that the second portion of the pixels and the second portion of the light-emitting diodes switch to the second display state synchronously, the second portion of the light-emitting diodes are switched to display a second display image, and the second portion of the pixels is switched to a transparent state.

16. The light-emitting diode display device of claim 15, wherein the switch controller is further configured such that the first portion of the pixels and the first portion of the light-emitting diodes switch to the second display state synchronously and such that the second portion of the pixels and the second portion of the light-emitting diodes switch to the first display state synchronously at a next frame, when the switch controller is configured such that the first portion of the pixels and the first portion of the light-emitting diodes switch to the second display state synchronously, the first portion of the light-emitting diodes is switched to display the second display image, and the first portion of the pixels is switched to a transparent state, when the switch controller is configured such that the second portion of the pixels and the second portion of the light-emitting diodes switch to the first display state synchronously, the second portion of the light-emitting diodes is switched to display the first display image, and the second portion of the pixels is switched to a reflection state.

17. The light-emitting diode display device of claim 1, wherein the switchable optical mirror has a plurality of subpixels, the subpixels and the light-emitting diodes are one-to-one corresponding, and a first portion of the subpixels corresponds to a first portion of the light-emitting diodes, a second portion of the subpixels corresponds to a second portion of the light-emitting diodes, the switch controller is configured such that the first portion of the subpixels and the first portion of the light-emitting diodes switch to the first display state synchronously and such that the second portion of the subpixels and the second portion of the light-emitting diodes switch to the second display state synchronously, when the switch controller is configured such that the first portion of the subpixels and the first portion of the light-emitting diodes switch to the first display state synchronously, the first portion of the light-emitting diodes is switched to display a first display image, and the first portion of the subpixels is switched to a reflection state, when the switch controller is configured such that the second portion of the subpixels and the second portion of the light-emitting diodes switch to the second display state synchronously, the second portion of the light-emitting diodes is switched to display a second display image, and the second portion of the subpixels is switched to a transparent state.

18. The light-emitting diode display device of claim 17, wherein the switch controller is further configured such that the first portion of the subpixels and the first portion of the light-emitting diodes switch to the second display state synchronously and such that the second portion of the subpixels and the second portion of the light-emitting diodes switch to the first display state synchronously at a next frame, when the switch controller is configured such that the first portion of the subpixels and the first portion of the light-emitting diodes switch to the second display state synchronously, the first portion of the light-emitting diodes is switched to display the second display image, and the first portion of the subpixels is switched to a transparent state, when the switch controller is configured such that the second portion of the subpixels and the second portion of the light-emitting diodes switch to the first display state synchronously, the second portion of the light-emitting diodes is switched to display the first display image, and the second portion of the subpixels is switched to a reflection state.

19. A light-emitting diode display device, comprising:
a translucent display panel having a plurality of light-emitting diodes;
a switchable optical mirror located at a side of the translucent display panel; and
a switch controller electrically connected the switchable optical mirror and the light-emitting diodes and configured to enable the switchable optical mirror and the light-emitting diodes to switch between a first display state and a second display state synchronously, wherein when in global switch mode, the switch controller is configured such that the switchable optical mirror and the light-emitting diodes switch to the second display state synchronously, the light-emitting diodes are switched to display a second display image, and the switchable optical mirror is switched to a global transparent state.

20. The light-emitting diode display device of claim 19, wherein when the switch controller is configured such that the switchable optical mirror and the light-emitting diodes switch to the first display state synchronously, the light-emitting diodes are switched to display a first display image, and the switchable optical mirror is switched to a global reflection state.
